(19) United States
(12) Patent Application Publication
(10) Pub. No.: US 2026/0282229 A1
(43) Pub. Date: Sep. 17, 2026

(54) SPRING ARRAY FRAME AND RELATED METHODS

(71) Applicant: Bal Seal Engineering, LLC, Foothill Ranch, CA (US)

(72) Inventors: Joshua Kompa, Foothill Ranch, CA (US); Erik Fort, Rancho Santa Margarita, CA (US); Mark Maloney, Missouri City, TX (US)

(73) Assignee: Bal Seal Engineering, LLC, Foothill Ranch, CA (US)

(21) Appl. No.: 19/471,945

(22) PCT Filed: Apr. 12, 2024
(86) PCT No.: PCT/US2024/024321

§ 371 Date: Oct. 2, 2025

Related U.S. Application Data
(60) Provisional application No. 63/496,273, filed on Apr. 14, 2023.

(51) Int. Cl. H05K 1/14; H05K 1/02

(52) U.S. Cl. CPC H05K 1/141; H05K 1/0201; H05K 2201/10424

(57) ABSTRACT

A frame assembly having a body and a plurality of prongs extending from an elongated edge or surface of the body. A canted coil spring length is located on one of the prongs and optionally each prong has a canted coil spring length located thereon. The prong can position the spring length at a neutral position or with a turning angle without a spring groove. The frame assembly can be used to conduct heat, transfer electricity, shield RF and EMI, and to test the spring length without a spring groove.

### CROSS-REFERENCE TO RELATED APPLICATION

This is a Section 371 national phase application of Ser. No. PCT/US 2024/024321, filed on Apr. 12, 2024, which claims priority to U.S. Provisional No. 63/496,273, filed Apr. 14, 2023, the contents of each of which are expressly incorporated herein by reference.

### FIELD OF ART

The present disclosure is generally directed to frame assemblies for use with cut spring lengths and more specifically to frame assemblies configured for holding one or more spring lengths and related methods.

### BACKGROUND

In applications that involve heat, heat dissipation is typically integrated into the application to manage or minimize heat buildup. Exemplary solutions include using heat sinks, serrated fins, fans, strategically placed insulation materials, and proper material selection.

In applications that involve electrical transfer, such as between two adjacent circuit boards, wires, and connectors, contact points may be used.

### SUMMARY

A frame assembly comprising: a body comprising a perimeter formed by a plurality of frame sections, including a first frame section and a second frame section, the perimeter defining an open space and each of the first and second frame sections comprising an inner edge; a first prong extending from the inner edge of the first frame section and extending towards the second frame section, the first prong having an attached end that is attached to the first frame section and a free end that is movable and located adjacent the second frame section; a second prong spaced from the first prong, the second prong extending from the inner edge of the first frame section or the second frame section and extending towards the other one of the second frame section or the first frame section, the second prong having an attached end that is attached to the first frame section or the second frame section and has a free end that is movable; and wherein the body is made from a metal material or a plastic material.

A spring mounted frame assembly comprising: a body comprising a perimeter formed by a plurality of frame sections, including a first frame section and a second frame section, the perimeter defining an open space and each of the first and second frame sections comprising an inner edge; a first prong extending from the inner edge of the first frame section and extending towards the second frame section, the first prong having an attached end that is attached to the first frame section and a free end that is movable and located adjacent the second frame section; a second prong spaced from the first prong, the second prong extending from the inner edge of the first frame section or the second frame section; a canted coil spring length comprising a plurality of interconnected coils and the plurality of interconnected coils having a coil center; and wherein the canted coil spring length is located on the first prong and the first prong is located in the coil center.

A method of using a spring length without a spring groove comprising: placing a canted coil spring length comprising a plurality of interconnected coils onto a first prong of a frame assembly having a perimeter formed by a plurality of frame sections, including a first frame section and a second frame section, the perimeter defining an open space and each of the first and second frame sections comprising an inner edge and wherein the first prong is attached to one of the inner edges and extends towards the other inner edge and is spaced from a second prong; deflecting the plurality of interconnected coils between two planar surfaces.

The perimeter defines a plane and wherein the first prong has two rounded ends defining a line along an end cross-section, and wherein the line is angled to the plane.

Each coil has a major axis and wherein the major axis of each coil is angled to the plane.

A method conducting heat in an electrical assembly comprising: placing a spring mounted frame assembly between a first board having a planar surface and a second board having a planar surface; and wherein the spring mounted frame comprising a canted coil spring length comprising a plurality of interconnected coils located on a first prong of a frame assembly having a perimeter formed by a plurality of frame sections, including a first frame section and a second frame section, the perimeter defining an open space and each of the first and second frame sections comprising an inner edge and wherein the first prong is attached to one of the inner edges and extends towards the other inner edge and is spaced from a second prong.

### BRIEF DESCRIPTION OF THE DRAWINGS

These and other features and advantages of the present devices, systems, and methods will become appreciated as the same becomes better understood with reference to the specification, claims and appended drawings wherein:

FIG. 1 is a schematic top perspective view of a frame assembly provided in accordance with aspects of the invention.

FIG. 2 is a side view of a spring length and an end view of a spring coil.

FIG. 3 is an end view showing the spring length mounted onto a leaf spring or prong of a frame assembly.

FIG. 4 is an end view showing the spring length mounted onto a leaf spring or prong of a frame assembly having a centerline that is angled to a plane to turn the spring length without a spring groove.

FIGS. 5 and 6 show different views of a spring mounted frame assembly.

FIG. 7 is a schematic view of an electrical assembly comprising one or more spring mounted frame assembly pressed between two adjacent plates.

FIG. 8 is schematic view of a test assembly showing a plate pressing a spring mounted frame assembly against a surface.

FIGS. 9A-9C depict another frame assembly for use with spring lengths in accordance with further aspects of the invention.

FIGS. 10A-10C depict yet another frame assembly for use with spring lengths in accordance with further aspects of the invention.

FIGS. 11A-11C depict still yet another frame assembly for use with spring lengths in accordance with further aspects of the invention.

FIGS. 12A-12D depict still yet another frame assembly for use with spring lengths in accordance with further aspects of the invention.

### DETAILED DESCRIPTION

The detailed description set forth below in connection with the appended drawings is intended as a description of the presently preferred embodiments of frame assemblies for heat dissipation and/or electrical transfer provided in accordance with aspects of the present devices, systems, and methods and is not intended to represent the only forms in which the present devices, systems, and methods may be constructed or utilized. The description sets forth the features and the steps for constructing and using the embodiments of the present devices, systems, and methods in connection with the illustrated embodiments. It is to be understood, however, that the same or equivalent functions and structures may be accomplished by different embodiments that are also intended to be encompassed within the spirit and scope of the present disclosure. As denoted elsewhere herein, like element numbers are intended to indicate like or similar elements or features.

Descriptions of technical features or aspects of an exemplary configuration of the disclosure should typically be considered as available and applicable to other similar features or aspects in another exemplary configuration of the disclosure. Accordingly, technical features described herein according to one exemplary configuration of the disclosure may be applicable to other exemplary configurations of the disclosure, and thus duplicative descriptions may be omitted herein.

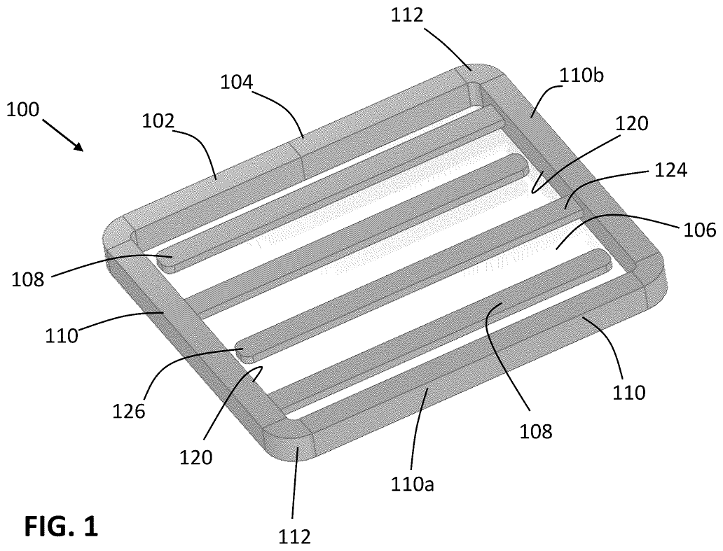

With reference now to FIG. 1, a perspective view of a frame or a frame assembly 100 in accordance with aspects of the invention is shown. In an example, the frame assembly 100 comprises a body 102 comprising a perimeter 104 defining an open space 106 having one or more prongs or leaf springs 108, which may also alternatively be referred to as a cantilever. As shown, the perimeter 104 is formed by four interconnected frame sections 110. In an example, the perimeter 104 has a quadrilateral shape, such as a rectangle shape or a square shape, formed by four interconnected frame sections 110. Where the frame sections 110 have different shapes or dimensions, the frame sections may be referred to as a first pair of frame sections 110a and a second pair of frame sections 110b, and so forth or by other nomenclatures to distinguish them by shapes or dimensions.

Connecting corner pieces 112, or connecting joints, are utilized to interconnect the frame sections 110. The connecting corner pieces 112 can have rounded corners, which are preferred, or sharp corners, such as 90-degree corners. The connecting corner pieces 112 and the frame sections 110 can be separately made and assembled via detents, snap-fit connections, fasteners, adhesive, or combinations thereof. Alternatively, the components 110, 112 can be assembled by brazing or welding if made from a metal material. The materials for the frame assembly can be selected accordingly for the desired application.

The components 110, 112 of the frame can have a cross-section with a length and a width, and less preferably round. Preferably, the perimeter 104 of the body 102 is made from a plastic material and formed by molding. Preferably, the entire frame assembly 100, including the one or more prongs 108, is formed by molding. When formed by molding or machining, there are no separate connecting corner pieces. In an alternative embodiment, the frame assembly 100, including the one or more prongs 108, is made from machining a metal stock material. Still alternatively, the frame assembly 100 is made from a combination of metal and plastic materials. The combination of metal and plastic materials can be assembled by adhesive or mechanical means. In still other examples, the frame section can be formed by stamping a metal blank.

One or more leaf springs or prongs 108 can extend from one of the frame sections 110, in the open space 106 defined by the perimeter of the frame 100. As shown, four leaf springs or prongs 108 extend from the inner edges 120 of the two second frame sections 110b. In other examples, there can be more than four leaf springs or less than four leaf springs. Each leaf spring or prong 108 has an attached end 124 that attaches to a corresponding inner edge 120 and a free end 126 that is not connected and is free standing. The prongs 108 can attach to the inner edges 120 by detents, snap fittings, adhesive, fasteners, or combinations thereof. Preferably, the prongs are unitarily formed with the perimeter.

Each prong 108 can have a cross-section that is configured to fit inside a spring length interior and position the coils of the spring length to seat at a desired coil angular position, as further discussed below. Each prong 108 has a free end 126 to allow the prong to deflect or bend about the attached end 124, similar to a leaf spring or a diving board. The ability to deflect allows a spring length to be loaded onto the prong, as further discussed below.

In the example shown, each prong 108 has a length that is about 75% to about 98% of the length of the perimeter 104 between the two inner edges 120. Preferably, each prong has a length that is about 90-95% of the length of the perimeter 104 between the two inner edges 120. The length can be selected to both permit deflection for mounting a spring length and prevent dislodgment following the spring length mounting. Thus, the far-most edge of the free end 126 should be sufficiently close to an adjacent inner edge 120 to prohibit inadvertent or unwanted dislodgement of the spring length at the free end. The free end preferably has a rounded tip to facilitate assembly of a spring length thereon, as further discussed below. The multiple prongs 108 are preferably straight and parallel to one another, in a spaced relationship.

As shown, the four prongs 110 have attached ends 124 that alternate between the two inner edges 120 of the two second frame sections 110b. In other examples, the alternating pattern can be different, such as two in a row attached to one inner edge and then the next two to the other inner edge. In yet another example, the attached ends 124 can all attach to the same inner edge 120 of one or the other second frame section 110b.

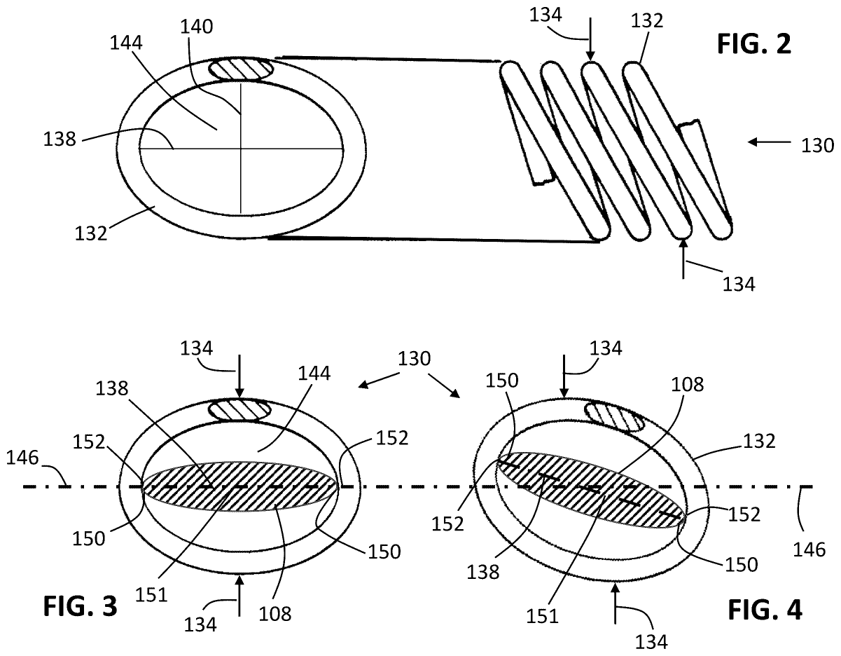

With reference now to FIG. 2, a side view of a spring length 130 having two unconnected ends is shown. The spring length can be cut to any desired length and can be made of any conductive metal wire materials, or from a multi-metallic construction with an inner metal core and one or more outer cladding layers. Additionally, while a round wire is contemplated, any wire cross-section, such as square, oval, polynomial, or triangular, may be used to form the spring length. The spring length 130 comprises a plurality of interconnected coils 132 with each coil generally canted along the same direction, such as generally to the left of FIG. 2. Generally, any number of coils per unit length of a spring length can be used with the frame assembly 100 of the present invention. The number of coils, spring lengths, and metallurgy can vary based on applications.

The spring length 130 is known in the industry as a canted coil spring that not only can expand and contract along its length like a typical extension spring but can also deflect in the radial direction to the length when a force 134 is applied to the coils in the radial direction to the spring length. The radial force, radial to the length of the spring, can cause the coils 132 to further cant in the same canting direction. In other words, the coils can start with a first canting angle and the canting angle changes to a different smaller or larger canting angle depending on the perspective of measurement of the original canting angle. The canting reverses when the radial force is removed. The radial force 134 can be applied from two spaced apart structures that have spaced apart parallel surfaces.

When looking at an end view of a coil 132 of the canted coil spring length 130, the coil 132 has an elliptical shape with two different axes 138, 140, with the longer of the two called a major axis 138 and the shorter of the two called a minor axis 140. Each coil also has a coil center 144 that passes through the centers of the interconnected coils 132. In other words, the coil center of the spring can be the interior space that passes through all the coils 132. The coils can also have certain coil spacing between them, and a front angle and a back angle, which determine the amount of canting in the rest position. Characteristically, the coils do further cant over from a rest position when a radial force is applied along the minor axis 130 but will not further cant or compress when a radial force is applied along the major axis 138. If excessive force is applied at the major axis 138 in an attempt to cant or deflect the coils in the radial direction relative to the length, then the coils may simply plastically deform. Thus, when a radial force is applied at the minor axis 140, the lowest amount of force is required to deflect the coils for a given amount. As the location of the radial force is moved away from the minor axis 140 towards the major axis 138, the force required to deflect the coil for the same deflection increases until a point in which no deflection is possible without physically deforming the coil. This situation can occur when the radial force is applied at the major axis, or just off the major axis but closer to the major axis than the minor axis. This concept is helpful for understanding the interactions between the spring length 130 and the cross-sectional shape of a prong 108 that the spring length is mounted on, as further discussed below.

With reference now to FIG. 3, an end view of a spring length 130 having a plurality of coils 132 (only one shown) and an end cross-sectional view of a prong or leaf spring 108 of a frame assembly 100 (FIG. 1) are shown. The spring length 130 can be mounted onto the prong 108 by deflecting the prong 108 at the free end 126 of the frame assembly 100 (FIG. 1) and then sliding the coils 132 over the prong so that the prong seats within the coil center 144 of the spring length 130. In the present example, the major axis 138 of the coils is generally horizontal and aligns with a plane 146 defined by the perimeter 104 of the frame assembly 100 (FIG. 1). The prong 108 is shown with an oblong shape cross-section having two rounded ends 150, 150. A straight line 151 connecting the two rounded ends 150, 150 can be considered the centerline 151 of the prong or leaf spring 108. The rounded ends 150, 150 of the prong are sized and shaped to have a size-on-size fit with the inside surfaces 152 of the plurality of coils 132 of the canted coil spring length 130 at the major axis 138 of the coils. However, a small play instead of a size-on-size fit between the two components at the major axis 138 is contemplated. Said differently, the length of the centerline 151 of the prong 108 and the major axis 138 of the coils are approximately equal. However, since some play is acceptable, the major axis 138 of the coils can be slightly larger than the length of the centerline 151.

Because of the fit between the prong 108 and the plurality of coils 132 of the spring length 130, and because the prong is attached to the perimeter 104 of the frame assembly 100 (FIG. 1) and cannot rotate relative to the frame, the coils 132 cannot rotate relative to the prong, or cannot materially rotate relative to the prong other than for some play between the two. Thus, by sizing the rounded ends 150, 150 of the prong relative to the inside surfaces 152, 152 of the coils and orienting the rounded ends, and therefore the orientation of the centerline 151, to sit a certain way relative to the plane 146 of the frame, the angular positions of the major and minor axes of the coils relative to the centerline 151 of the prong can be selected or controlled. As further discussed below with reference to FIG. 4, by controlling the angular position of the centerline of the prong 108 and sizing the prong to fit within the coil centerline 144, this allows the coils 132 of the spring length 130 to be oriented to a desired turning angle without the need for a machined groove, which is typically necessary to position the coils to any desired turning angle. In other words, the turning angle of the coils can be adjusted or rotated to a desired turning angle by manipulating the inside surfaces 132 of the coils rather than the outside surfaces via a machined groove.

With reference again to FIG. 3, the coils 132 are shown at a zero turning angle, which is the position in which the major axis 138 of the coils is parallel with the plane 146 of the frame assembly 100. In the orientation shown, when a radial force 134 is applied to the coils, the coils can deflect or cant along their respective minor axis 140 and the presence of the prong 108 does not affect the deflection since the coils do not deflect along the major axis 138. Thus, the frame assembly 100 holds the spring length 130 in place and provides the ability to deflect the coils 132 outside of a spring groove.

FIG. 4 is a similar view as FIG. 3 but wherein the straight line between the two rounded ends 150, 150 of the prong 108, i.e., the centerline 151 of the prong, is oriented at an angle to the plane 146 of the frame assembly. Thus, due to the constraint of the two inside surfaces 152, 152 of the coils 132 by the two rounded ends 150, 150 of the prong, the coils are also rotated by the prong to a turning angle, in which the major axis 138 (FIG. 2) of the coils is angle to the plane 146. Thus, the frame assembly 100, and specifically the respective prong 108, holds the spring length 130 in place and turns the major axis of the coils to provide the ability to position the coils 132 at a turning angle outside of a spring groove.

When a radial force 134 is applied to the coils of FIG. 4, such as from two spaced apart structures with parallel surfaces that press against the coils, and because the coils are positioned at a turning angle, the forces are applied at locations away from the minor axis 140. The radial canting force 134 is therefore higher to cant the coils a canting deflection amount than the radial force required to cant the coils the same canting deflection amount for the coils of FIG. 3, which does not have a turning angle. Thus, the frame assembly 100 provides for the ability to position the coils 132 of the spring length 130 at a turning angle and the ability to deflect the coils 132 of the turned spring outside of a spring groove.

In some examples, the orientation of the prong 108, such as of the centerline 151 connecting the two rounded ends 150, 150 relative to the plane 146, can be rotated to a different turning angle than shown, and can be rotated counterclockwise instead of clockwise as shown.

In some examples, all of the prongs or leaf springs 108 of a frame assembly 100 can be orientated relative to the plane of the frame the same amount or different amounts. For example, when used to contact two adjacent circuit boards, the prong of the frame assembly can be similarly oriented. In other examples, such as where it is desired to use a single frame assembly to test multiple different coil positions, such as with zero turning angle and with increments of a few degrees, the different prongs 108 can be oriented at different angles when integrated with the perimeter 104 of the frame. Thus, depending on which of the prongs the spring length is mounted onto, different turning angle and different canting forces can be tested to deflect the coils of the spring outside of a spring groove.

In FIGS. 3 and 4, the cross-section of the prongs or leaf springs 108 is shown as an oblong shape. However, the cross-sectional shape of the prong can embody other shapes. The shape selected should have two ends defining a centerline having a length that has a size-on-size fit with inside surfaces of the coils' major axis 138 and not interfere with the coils' deflection.

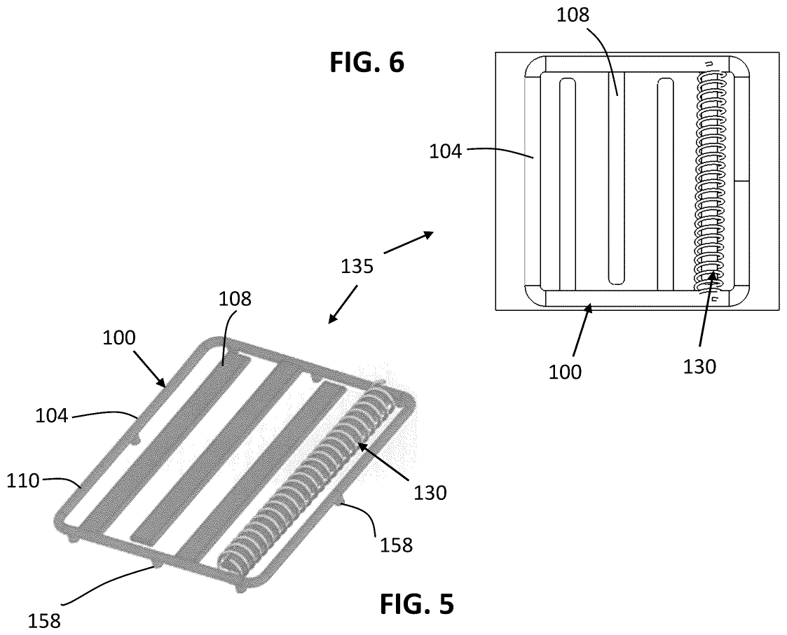

With reference now to FIGS. 5 and 6, a perspective view and a top view of a spring length 130 mounted on a prong 108 of a frame assembly 100 is shown. The frame assembly 100 has one or more prongs 108 and at least one spring length located on one of the prongs may be referred to as a spring mounted frame assembly 135.

As discussed above, the spring length 130 can be mounted by deflecting the prong at the free end 126 of the prong to clear the perimeter 104 of the frame and then sliding the spring length 130 onto the prong. When the deflection force to deflect the prong is released, the prong 108 can return to its rest or undeflected position shown with the spring length 130 of FIGS. 5 and 6.

The spring length 130 is shown having a length that occupies approximately the entire length defined by the two inner edges 120 (FIG. 1) of the frame, approximately the same length as the prong 108, or can have a spring length that is less than the length of the prong. Preferably, the spring length is shorter than the length defined by the two inner edges 120, 120 of the frame, also referred to as the frame inside width. When the spring length is appropriately sized to not compress by the frame inside width, there is no compression force on the length of the spring that can otherwise affect the radial deflection force of the spring. However, some contact with the inner edges 120, 120 should not materially affect the radial deflection. While only one spring length 130 is shown located on the frame assembly 100, there can be two spring lengths mounted or up to the number of spring lengths as there are prongs 108.

Optional foot support tabs 158 may be provided with the frame assembly 100. The foot support tabs 158 can be placed throughout the lower surface of the perimeter 104 to support the frame and to elevate the springs 130 above a table or surface that the spring mounted frame assembly 135 is placed on. The foot support tabs 158 can be unitarily formed with the frame assembly or separately formed and subsequently attached to the frame, such as by adhesive or mechanical means.

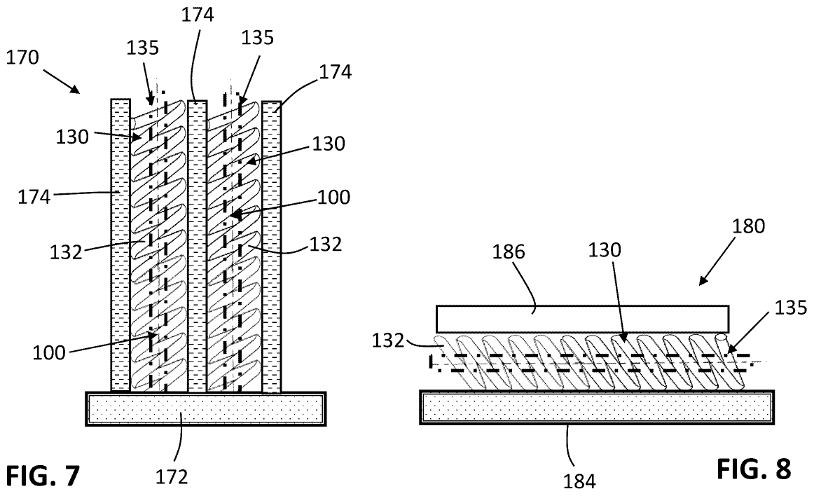

FIG. 7 is a schematic elevation side view of an electrical assembly 170 having a main board 172 and a plurality of secondary boards 174 connected to the main board 172. The primary and secondary boards can be circuit boards, mother boards, or other printed circuit (PC) boards. However, any number of main board and secondary board arrangements may be used with the spring mounted frame assemblies 135 of the present invention. The electrical assembly 170 is representative of any number of equipment or devices that generate heat and/or conduct electricity. In the embodiment shown, a spring mounted frame assembly 135 is located between two adjacent secondary boards 174 and the two boards 174 compress the coils 132 of the one or more spring lengths 130 located on the frame assembly 100 of the spring mounted frame. When used in the manner shown and described, the spring mounted frame assemblies 135 can dissipate heat by conduction by allowing heat from one secondary board to transfer heat to another secondary board, especially when one secondary board is operating at a higher temperature than the other. In other examples, the spring mounted frame assembly 135 can be used as shown in between PC boards and the like for radio frequency (RF) and electromagnetic interference (EMI) shielding, such as to protect sensitive components from internal and/or external to emitting sources.

In other examples, only two secondary boards 174 or more than three secondary boards 174 may be used with fewer or high number of spring mounted frame assemblies.

In other examples, the electrical assembly 170 is an electric power switch comprising three different blade contacts 174. Electrical transfer between the different blade contacts 174 can be carried out by using spring mounted frame assemblies 135 with each spring mounted frame comprising one or more canted coil spring lengths 130 located between two adjacent blade contacts 174. The two adjacent blade contacts 174 have a gap between them that are sized to squeeze the one or more canted coil spring lengths 130 to cant the coils to generate biasing forces by the coils against the two adjacent blade contacts. The centerline 151 between two ends of each of the prongs 108 of the spring mounted frame assembly 135 can be angled or parallel relative to the plane defined by the perimeter 104 as previously discussed. If angled, then the coils can be rotated to a turning angle without a spring groove, as previously discussed.

FIG. 8 depicts a schematic elevation view of a test assembly 180. The test assembly can comprise a table or a test bench 184 comprising surface. A spring mounted frame assembly 135 with one or more spring lengths 130 can be placed on the surface of the test bench 184 and then an actuating flange 186 can press on the one or more spring lengths 130 to deflect the coils 132. This allows the user to evaluate the force versus deflection of the one or more spring lengths without a spring groove. The centerline 151 between two ends of a prong of the multiple prongs 108 of the spring mounted frame assembly 135 can be angled or parallel relative to the plane defined by the perimeter 104 as previously discussed.

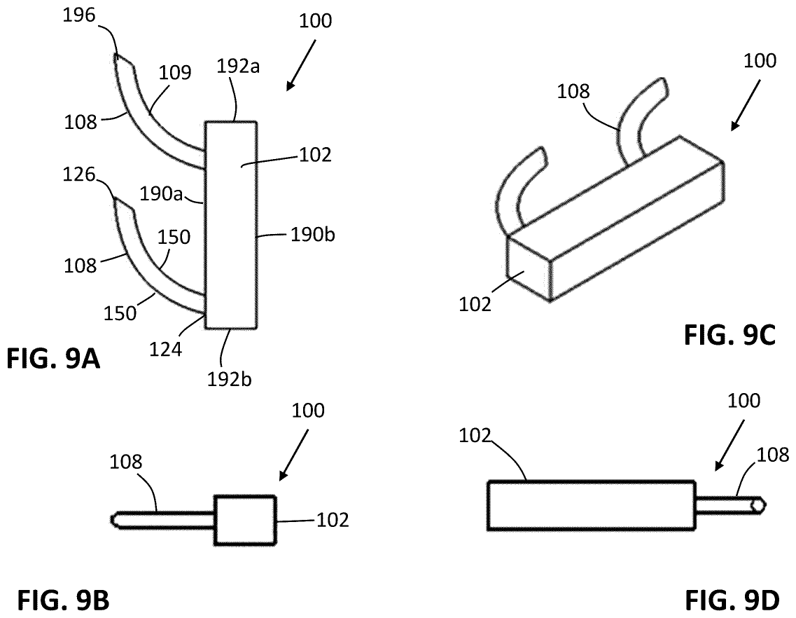

With reference now to FIG. 9A-9D, different views of another frame assembly 100 for positioning spring lengths 130 (FIG. 2) in accordance with aspects of the invention are shown. The frame assembly 100 of the present embodiment comprises a body 102 and at least two prongs or leaf springs 108 extending from the body 102. In an example, the body 102 is elongated and has a generally rectangular prism construction with a plurality of sides, including a first elongated side 190a, a second elongated side 190a, a first end side 192a, and a second end side 192b. The body 102 is preferably solid between the plurality of sides.

In an example, a plurality of prongs or leaf springs 108 extend from one of the elongated sides, such as the first elongated side 190a. Each prong 108 has a fixed end or attached end 124 where the prong attaches to the body 102 and a free end 126 that does not attach to any structure and is free standing. In the present embodiment, each prong has a body 109 that is not straight like that shown in FIG. 1 but curves or is arcuate.

The body 109 of the prong is generally constant along the length of the prong from the fixed end to the free end. As shown, the free end 126 as a straight or linear terminal end 196. The straight terminal end 196 allows a spring length to readily slide onto the body 109 and bends as the spring slides on to comply with the curve of the body. The end cross-section of the body 109 can have an oblong shape as shown in FIGS. 3 and 4 with rounded ends 150 to form fit against the interior or inside surface of the coils 132 of the spring length. This then allows the straight line between the two rounded ends 150 to be rotated to change the turning angle of the coils, as previously discussed.

In other examples, the prong end cross-section can have a different shape than an oblong shape. For example, prong can have an elliptical shape, a rectangular shape, other polynomial shapes, or an irregular shape.

In the example shown, two prongs 108 extend from the first elongated side 190a of the body. In other examples, one or more prongs extend from both elongated sides 190a, 190b of the body 102. Further, the number of prongs and the locations of the fixed ends 124 of the prongs can be symmetrical or non-symmetrical along the lengthwise axis passing through the body, and the number of prongs on each side of the lengthwise axis can be the same or different. In still other examples, the orientation of the free ends 126 of the prongs, on each side of the body, can extend in the same direction or in the opposite direction.

When one or more spring lengths are mounted onto the prongs of the present embodiment, the frame assembly 100 may be referred to as a spring mounted frame assembly. Such spring mounted frame assembly may be used to dissipate heat by facilitating heat conduction and/or conduct electricity. In other examples, the spring mounted frame assembly can be used for radio frequency (RF) and electromagnetic interference (EMI) shielding, such as to protect sensitive components from internal and/or external to emitting sources.

FIG. 9B shows an end elevation view of the frame assembly 100 of FIG. 9A, FIG. 9C shows a perspective view of the frame assembly of FIG. 9A, and FIG. 9D shows a side elevation view of the frame assembly of FIG. 9A.

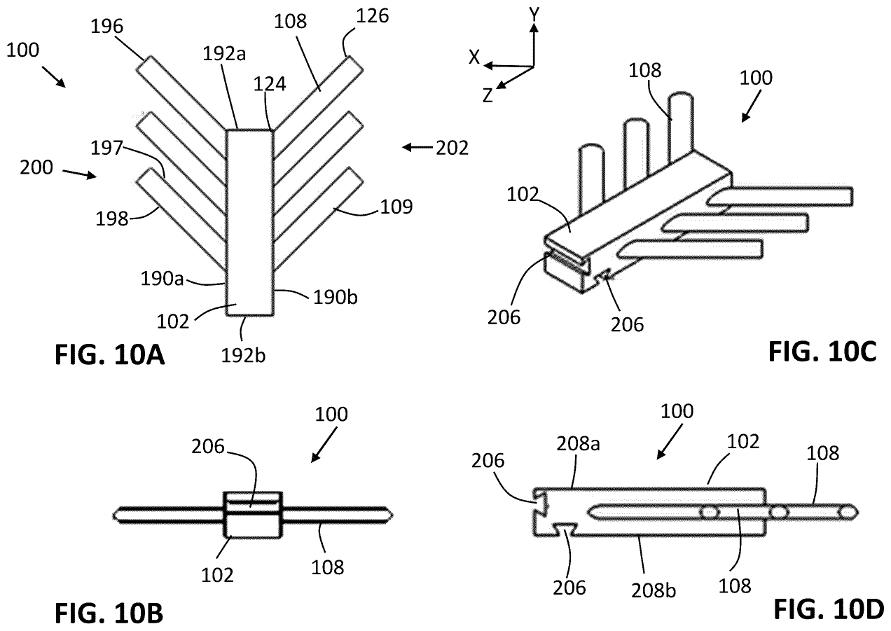

With reference now to FIGS. 10A-10D, different views of yet another frame assembly 100 for positioning spring lengths 130 (FIG. 2) in accordance with further aspects of the invention are shown. The frame assembly 100 of the present embodiment comprises a body 102 and at least two prongs or leaf springs 108 extending from both first and second elongated sides the body 102, similar to that shown in FIG. 9A. In an example, the body 102 is elongated and has a generally rectangular prism construction with a plurality of sides, including a first elongated side 190a, a second elongated side 190b, a first end side 192a, and a second end side 192b. The body 102 is preferably solid between the plurality of sides.

In an example, a plurality of prongs or leaf springs 108 extend from both elongated sides 190a, 190b of the body, with extension from one side being a permissive alternative. Each prong 108 has a fixed end or attached end 124 where the prong attaches to the body 102 and a free end 126 that does not attach to any structure and is free standing. In the present embodiment, each prong has a body 109 that is generally straight, similar to the prongs of FIG. 1. However, rather than extending orthogonally relative to the surfaces of the first and second elongated sides 190a, 190b, the prongs 108 extend at an angle such that the front or forward edge 197 of each prong 108 forms an acute angle with the respective first or second elongated side 190a, 190b. In an example, the acute angle is from about 25 degrees to about 85 degrees, with 37 degrees to 50 degrees being more preferred. In other examples, each of the prongs extends orthogonally relative to the surfaces of the first and second elongated sides 190 a, 190 b, so that the forward edge 197 is about 90-degrees to the respective first or second elongated side.

In an example, a plurality of prongs 108 extend from each elongated side of the two sides 190a, 190b of the body 102 of the frame assembly 100. Depending on the length of body 102 between the two end sides 192a, 192b, there can be two or more prongs extending on each of the two sides of the body. For example, for a frame assembly with a short body, there can be two prongs extending on each side of the body. For a longer length body, there can be more than two prongs, such as three or more, four or more, five or more, six or more, etc.

The width of each prong between the front or forward edge 197 and the rear or trailing edge 198 can vary depending on the size of the canted coil spring length to be mounted onto the prong. Each prong can have an oblong shape, an elliptical shape, a rectangular shape, other polynomial shapes, or an irregular shape. The cross-sectional shape should be selected so that the prong can retain the inside surfaces 152 of the coils 132 as shown and described with reference to FIGS. 3 and 4.

In an example, the two sets of prongs on each side of the body 102 of the frame assembly can be symmetrical about the lengthwise axis passing through the first and second end sides 192a, 192b as shown. In other examples, the two sets of prongs can be non-symmetrical. For example, the first set 200 of prong 108 can be shifted up or back relative to the second set 102 of prongs. The two sets of prongs can also have a different number of prongs. In other examples, the angles that the prongs extend along the first elongated side 190a and along the second elongated side 190b can differ. In still other examples, the spacing between two adjacent prongs can be different within the same set of prongs or when comparing the two sets of prongs 200, 202.

In an example, the prongs 108 can be unitarily formed with the body 102 of the frame assembly, such as when forming the frame assembly 100 from a thermoplastic or an engineered plastic material. In other examples, the prongs may be threaded to the body, may be welded to the body, may be bonded to the body, such as with an adhesive, or may be attached to the body by press-fit. The frame assembly may be made from a metal material or a non-metal material.

FIG. 10B is an end view of the frame assembly 100 of FIG. 10A, FIG. 10C is a side perspective view of the frame assembly, and FIG. 10D is a side view of the frame assembly. In an example, the body can optionally incorporate a slot or a track 206 on the second end side 192b of the body. In an example, the slot 206 can embody a dove tail groove. The slot 206 from one frame assembly 100 can be used to couple to a projection or a complementary mating structure, such as a tongue, from another frame assembly 100 to allow for expansion of the number of prongs 108. That is, for a plane in the X-Y direction of the 2D view of FIG. 10A, incorporation of the slot or track 206 at the second end side 192b of the body 102 allows for expansion in the X-Y direction of the bodies 102 and the prongs 108. In still other examples, an external coupling having two projections or two complementary mating structures can be used to couple two frame assemblies to together. For example, two frame assemblies 100 each with the configuration shown in FIG. 10C can be secured to one another with the described coupling located between them and securing against the two slots or tracks.

Each frame assembly 100 can optionally incorporate a second slot or track 206. The second track 206 can embody the same or different structure as the first track 206 located on the second end side 192b. The second track 206 can be located on a different side of the body 102 than the first track. In an example, the second track 206 is provided on one of the upper side 208a or the lower side 208b, and the two open ends of the second channel can originate at the two elongated sides 190a, 190b. With reference to the XYZ axis reference of FIG. 10A, the second track 206 can have a dove tail structure and can be used to expand the frame structure 100 in the Z direction. Two frame structures 100 can be combined to expand in the Z direction by utilizing complementary tongue and groove latching structures. Alternatively, a separately formed coupling can be used to combine two adjacent frame structures 100.

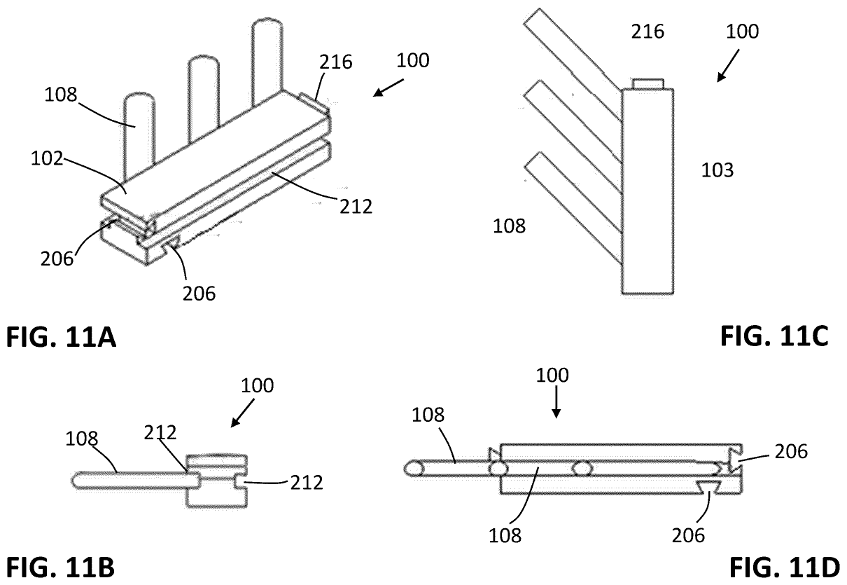

With reference now to FIGS. 11A-11D, different views of yet another frame assembly 100 for positioning spring lengths 130 (FIG. 2) in accordance with still further aspects of the invention are shown. The frame assembly 100 of the present embodiment comprises a body 102 and at least two prongs or leaf springs 108 extending from the body 102, similar to that shown in FIGS. 10A-10D. Although only one set of prongs 200 are shown extending from the first elongated side 190a of the body, a second set of prongs can extend from the second elongated side 190b, similar to that shown in FIGS. 10A-10D. However, in the present embodiment, both the first and second elongated sides 190a, 190b incorporate attachment channels 212 along the length of the body 102. Each attachment channel is sized and shaped to receive a prong 108 with each prong having a complementary structure for attaching to the attachment channel 212 at a fixed end 124 of the prong. Optionally, the attached prong 108 can slide along the length of the attachment channel 212 to a desired position and/or spacing relative to another attached prong.

A projection 216 extends outwardly from the first end side 192a of the body 102. The projection 216 can have complementary structure for engaging the track 206 on the second end side 192b of another frame assembly 100. Thus, the projection 216 and the track 206 allow for two frame assemblies 100 to connect and expand. In some examples, the projection 216 may be used to attach to the second track 206 located on the lower side 208a of the body to form an expanded frame assembly 100.

Spring lengths can be mounted onto the prongs 108 as discussed elsewhere herein.

FIG. 11B is an end view of the frame assembly of FIG. 11A, FIG. 11C is a top view of the frame assembly of FIG. 11A, and FIG. 11D is a side view of the frame assembly of FIG. 11D, looking at the first set of prongs.

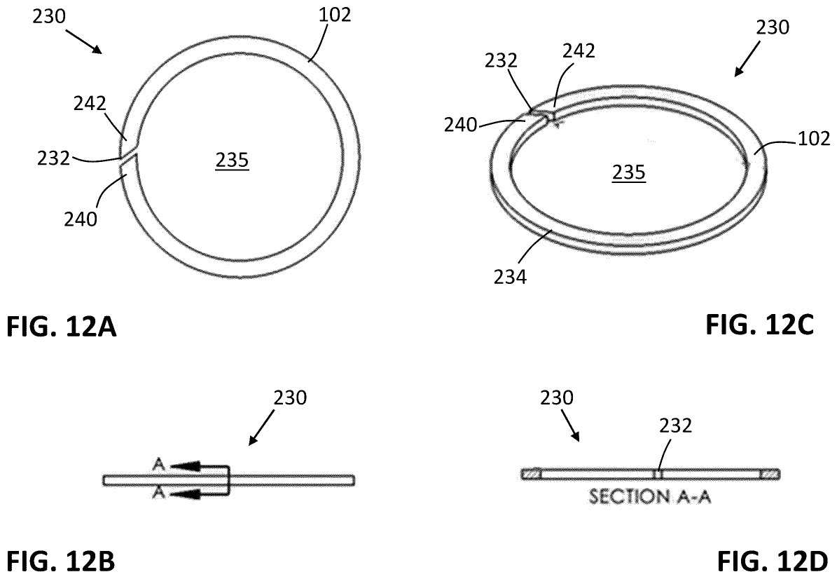

With reference now to FIGS. 12A-12D, different views of yet another frame assembly 230 for positioning a spring length 130 (FIG. 2) in accordance with still further aspects of the invention are shown. The frame assembly 230 of the present embodiment comprises a body 102 having a loop configuration with a break or a slot 232 so as to define a non-continuous loop 234 having a central loop opening 235. The non-continuous loop 234 can have a generally circular configuration although an elliptical or oblong loop are contemplated.

The break or slot 232 defines two free ends 240, 242, which a user can grab and manipulate to flex the two ends out of alignment to then mount a spring length onto the body 102 of the non-continuous loop 234. The body 102 can have a cross-sectional shape between the ID and the OD that is similar to the other prongs 108 discussed elsewhere herein. In some examples, the body 102 can turn so that the axis passing between the OD and the ID is not flat relative to a working surface. In other words, the rotated body can resemble a truncated frusto-conical shape structure. Thus, when a spring length is mounted onto the rotated body 102, the spring length can be positioned at a turning angle. The diameter of the body 102 can vary and the cross-sectional size of the body 102 can vary depending on the spring length and the size of the coils of the spring length.

The body 102 of the frame assembly 230 can be formed with a metallic material or a non-metallic material, such as a ceramic, a thermoplastic, or a composite material.

FIG. 12B is a side view of FIG. 12A, FIG. 12C is a perspective view of FIG. 12A, and FIG. 12D is a side view taken along line A-A of FIG. 12B.

### EXAMPLE EMBODIMENTS

The following are numbered example embodiments of the apparatuses, devices, systems, and methods related to frame structures and spring mounted frame structures to use in heat transfer, electrical conductivity, RF shielding, and/or EMI shielding. Examples 1-60 or any other examples disclosed herein may be combined in whole or in part. Elements of the examples disclosed herein, if applicable, are not limiting.

Example 1. A frame assembly comprising: a body comprising a perimeter formed by a plurality of frame sections, including a first frame section and a second frame section, the perimeter defining an open space and each of the first and second frame sections comprising an inner edge; a first prong extending from the inner edge of the first frame section and extending towards the second frame section, the first prong having an attached end that is attached to the first frame section and a free end that is movable and located adjacent the second frame section; a second prong spaced from the first prong, the second prong extending from the inner edge of the first frame section or the second frame section and extending towards the other one of the second frame section or the first frame section, the second prong having an attached end that is attached to the first frame section or the second frame section and has a free end that is movable; and wherein the body is made from a metal material or a non-metallic material.

Example 2. The frame assembly or spring mounted frame assembly, system, device, and method of any of Examples 1-60 or any other embodiment described herein, wherein the second prong extends from the inner edge of the second frame, and further comprising a third prong.

Example 3. The frame assembly or spring mounted frame assembly, system, device, and method of any of Examples 1-60 or any other embodiment described herein, wherein the non-metallic material is ceramic or thermoplastic.

Example 4. The frame assembly or spring mounted frame assembly, system, device, and method of any of Examples 1-60 or any other embodiment described herein, wherein the first prong has a cross-sectional shape that is oblong or elliptical.

Example 5. The frame assembly or spring mounted frame assembly, system, device, and method of any of Examples 1-60 or any other embodiment described herein, wherein the second prong has a cross-sectional shape that is rectangular or a polynomial shape.

Example 6. The frame assembly or spring mounted frame assembly, system, device, and method of any of Examples 1-60 or any other embodiment described herein, wherein the free end of the first prong is movable to separate a gap between the free end and the second frame section from a first gap to a second gap, which is larger than the first gap.

Example 7. The frame assembly or spring mounted frame assembly, system, device, and method of any of Examples 1-60 or any other embodiment described herein, wherein a spring length having two spaced apart ends is mounted onto the first prong.

Example 8. The frame assembly or spring mounted frame assembly, system, device, and method of any of Examples 1-60 or any other embodiment described herein, wherein a second spring length is mounted onto the second prong.

Example 9. The frame assembly or spring mounted frame assembly, system, device, and method of any of Examples 1-60 or any other embodiment described herein, wherein the spring length has a plurality of interconnected coils and each of the coil has a major axis and a minor axis.

Example 10. The frame assembly or spring mounted frame assembly, system, device, and method of any of Examples 1-60 or any other embodiment described herein, wherein the major axis of each coil is rotated relative to the ground and is held at a turning angle by contact between the first prong and an inside surface of the coil.

Example 11. The frame assembly or spring mounted frame assembly, system, device, and method of any of Examples 1-60 or any other embodiment described herein, wherein the first prong is unitarily formed with the perimeter.

Example 12. The frame assembly or spring mounted frame assembly, system, device, and method of any of Examples 1-60 or any other embodiment described herein, wherein the first prong is attached to the perimeter.

Example 13. The frame assembly or spring mounted frame assembly, system, device, and method of any of Examples 1-60 or any other embodiment described herein, further comprising a third prong and a fourth prong, and wherein each of the first, second, third, and fourth prongs has a spring length mounted thereon.

Example 14. The frame assembly or spring mounted frame assembly, system, device, and method of any of Examples 1-60 or any other embodiment described herein, further comprising a third prong and a fourth prong, and wherein at least one spring length is mounted on one of the first, second, third, and fourth prongs.

Example 15. The frame assembly or spring mounted frame assembly, system, device, and method of any of Examples 1-60 or any other embodiment described herein, wherein the frame assembly is located between two PC boards to provide at least one of heat transfer, RF shielding, and EMI shielding.

Example 16. The frame assembly or spring mounted frame assembly, system, device, and method of any of Examples 1-60 or any other embodiment described herein, further comprising a plurality of spaced apart foot support tabs mounted to the perimeter.

Example 17. The frame assembly or spring mounted frame assembly, system, device, and method of any of Examples 1-60 or any other embodiment described herein, wherein a canted coil spring length having two spaced appart ends and a plurality of interconnected coils is mounted onto the first prong or the second prong.

Example 18. The frame assembly or spring mounted frame assembly, system, device, and method of any of Examples 1-60 or any other embodiment described herein, wherein a second canted coil spring length having two spaced appart ends and a plurality of interconnected coils is mounted onto the other one of the first prong or the second prong.

Example 19. The frame assembly or spring mounted frame assembly, system, device, and method of any of Examples 1-60 or any other embodiment described herein, wherein the first prong and the second prong are part of a plurality of spaced apart prongs, and wherein each of the plurality of prongs has a fixed end that is attached to the perimeter in alternating pattern.

Example 20. The frame assembly or spring mounted frame assembly, system, device, and method of any of Examples 1-60 or any other embodiment described herein, wherein the first prong and the second prong are part of a plurality of spaced apart prongs, and wherein each of the plurality of prongs has a fixed end that is attached to the first frame section or the second frame section.

Example 21. The frame assembly or spring mounted frame assembly, system, device, and method of any of Examples 1-60 or any other embodiment described herein, wherein the first prong and the second prong are part of a plurality of spaced apart prongs, and wherein each of the plurality of prongs has a fixed end and half of the plurality of prongs have fixed ends that are attached to the first frame section and the other half of the plurality of prongs have fixed ends that are attached the second frame section.

Example 22. A spring mounted frame assembly comprising: a body comprising a perimeter formed by a plurality of frame sections, including a first frame section and a second frame section, the perimeter defining an open space and each of the first and second frame sections comprising an inner edge; a first prong extending from the inner edge of the first frame section and extending towards the second frame section, the first prong having an attached end that is attached to the first frame section and a free end that is movable and located adjacent the second frame section; a second prong spaced from the first prong, the second prong extending from the inner edge of the first frame section or the second frame section; a canted coil spring length comprising a plurality of interconnected coils and each of the plurality of interconnected coils has a coil center; and wherein the canted coil spring length is located on the first prong and the first prong is located in the coil center of at least five coils.

Example 23. The frame assembly or spring mounted frame assembly, system, device, and method of any of Examples 1-60 or any other embodiment described herein, wherein each coil has an inside surface circumscribing the coil center, and wherein the first prong contacts the inside surface of the at least five coils.

Example 24. The frame assembly or spring mounted frame assembly, system, device, and method of any of Examples 1-60 or any other embodiment described herein, wherein each of the at least five coils has a major axis and wherein the major axis is rotated by the first prong so that the major axis is angled to the ground.

Example 25. The frame assembly or spring mounted frame assembly, system, device, and method of any of Examples 1-60 or any other embodiment described herein, wherein a second spring length is mounted on the second prong.

Example 26. The frame assembly or spring mounted frame assembly, system, device, and method of any of Examples 1-60 or any other embodiment described herein, wherein the first and second prongs are part of a plurality of prongs, and wherein a spring length is located on each of the plurality of prongs.

Example 27. The frame assembly or spring mounted frame assembly, system, device, and method of any of Examples 1-60 or any other embodiment described herein, wherein the body is made from a metallic material or a non-metallic material.

Example 28. The frame assembly or spring mounted frame assembly, system, device, and method of any of Examples 1-60 or any other embodiment described herein, wherein the non-metallic material is ceramic or plastic.

Example 29. The frame assembly or spring mounted frame assembly, system, device, and method of any of Examples 1-60 or any other embodiment described herein, wherein first and second prongs are made from a same material as the body.

Example 30. A method of using a spring length without a spring groove comprising: placing a canted coil spring length comprising a plurality of interconnected coils onto a first prong of a frame assembly having a perimeter formed by a plurality of frame sections, including a first frame section and a second frame section, the perimeter defining an open space and each of the first and second frame sections comprising an inner edge and wherein the first prong is attached to one of the inner edges and extends towards the other inner edge and is spaced from a second prong; and deflecting the plurality of interconnected coils between two planar surfaces.

Example 31. The frame assembly or spring mounted frame assembly, system, device, and method of any of Examples 1-60 or any other embodiment described herein, wherein the perimeter defines a plane and wherein the first prong has two rounded ends defining a line along an end cross-section, and wherein the line is angled to the plane.

Example 32. The frame assembly or spring mounted frame assembly, system, device, and method of any of Examples 1-60 or any other embodiment described herein, wherein each coil has a major axis and wherein the major axis of each coil is angled to the plane.

Example 33. The frame assembly or spring mounted frame assembly, system, device, and method of any of Examples 1-60 or any other embodiment described herein, wherein the first prong contacts an inside surface of each of the plurality of interconnected coils to turn the major axis.

Example 34. The frame assembly or spring mounted frame assembly, system, device, and method of any of Examples 1-60 or any other embodiment described herein, wherein deflecting the plurality of interconnected coils between two planar surfaces comprise deflecting the interconnected coils between a first board and a second board.

Example 35. The frame assembly or spring mounted frame assembly, system, device, and method of any of Examples 1-60 or any other embodiment described herein, wherein the spring length provides at least one of heat transfer, RF shielding, and EMI shielding.

Example 36. A method of providing at least one of conducting heat, shielding RF, and shield EMI in an electrical assembly comprising: placing a spring mounted frame assembly between a first board having a planar surface and a second board having a planar surface; and wherein the spring mounted frame assembly comprising a canted coil spring length comprising a plurality of interconnected coils located on a first prong of a frame assembly having a perimeter formed by a plurality of frame sections, including a first frame section and a second frame section, the perimeter defining an open space and each of the first and second frame sections comprising an inner edge and wherein the first prong is attached to one of the inner edges and extends towards the other inner edge and is spaced from a second prong.

Example 37. The frame assembly or spring mounted frame assembly, system, device, and method of any of Examples 1-60 or any other embodiment described herein, wherein the spring mounted frame assembly comprises a plurality of prongs, including the first prong, and wherein each of the plurality of prongs as a canted coil spring length mounted thereon.

Example 38. A spring mounted frame assembly comprising: a body comprising a body having an elongated side; a plurality of spaced apart prongs extending from the elongated side, each prong having a fixed end extending from the elongated side and a free end that is unconnected; a spring length comprising a plurality of interconnected coils mounted on at least one of the prongs; and wherein each prong has a cross-sectional shape that is not circular.

Example 39. The frame assembly or spring mounted frame assembly, system, device, and method of any of Examples 1-60 or any other embodiment described herein, wherein the elongated side is a first elongated side and the plurality of spaced apart prongs are part of a first set of prongs; and wherein the body further comprising a second elongated side opposite the first elongated side a second set of prongs comprising a plurality of prongs extend from the second elongates side.

Example 40. The frame assembly or spring mounted frame assembly, system, device, and method of any of Examples 1-60 or any other embodiment described herein, further comprising a track or groove located on an end side that is angled to the elongated side.

Example 41. The frame assembly or spring mounted frame assembly, system, device, and method of any of Examples 1-60 or any other embodiment described herein, further comprising a track or groove located on an upper side or a lower side of the body.

Example 42. The frame assembly or spring mounted frame assembly, system, device, and method of any of Examples 1-60 or any other embodiment described herein, wherein the elongated side has an attachment channel and each of the plurality of spaced apart prongs is attached to the attachment channel.

Example 43. The frame assembly or spring mounted frame assembly, system, device, and method of any of Examples 1-60 or any other embodiment described herein, further comprising a projection extending from an end side that is angled to the elongated side.

Example 44. The frame assembly or spring mounted frame assembly, system, device, and method of any of Examples 1-60 or any other embodiment described herein, wherein each of the plurality of prongs has a curved body.

Example 45. The frame assembly or spring mounted frame assembly, system, device, and method of any of Examples 1-60 or any other embodiment described herein, further comprising a lip or a shoulder at the free end of each prong configured for retaining a spring length.

Example 46. The frame assembly or spring mounted frame assembly, system, device, and method of any of Examples 1-60 or any other embodiment described herein, wherein the projection connects to a track or groove on a second body.

Example 47. The frame assembly or spring mounted frame assembly, system, device, and method of any of Examples 1-60 or any other embodiment described herein, further comprising a coupling connected to the track or groove and the coupling connected to a track or a groove of a second body.

Example 48. The frame assembly or spring mounted frame assembly, system, device, and method of any of Examples 1-60 or any other embodiment described herein, wherein the first set of prongs and the second set of progs are symmetrical about a lengthwise axis extending through the body.

Example 49. The frame assembly or spring mounted frame assembly, system, device, and method of any of Examples 1-60 or any other embodiment described herein, wherein the first set of prongs and the second set of progs are asymmetrical about a lengthwise axis extending through the body.

Example 50. The frame assembly or spring mounted frame assembly, system, device, and method of any of Examples 1-60 or any other embodiment described herein, wherein the prongs of the first set of prongs are spaced from one another a first gap and the prongs of the second set of progs are spaced from one another a second gap, and wherein the first gap and the second gap are unequal.

Example 51. The frame assembly or spring mounted frame assembly, system, device, and method of any of Examples 1-60 or any other embodiment described herein, wherein each prong forward edge and wherein the forward edge of each prong forms an acute angle with the elongated side.

Example 52. The frame assembly or spring mounted frame assembly, system, device, and method of any of Examples 1-60 or any other embodiment described herein, wherein the acute angle is between 35 and 55 degrees.

Example 53. The frame assembly or spring mounted frame assembly, system, device, and method of any of Examples 1-60 or any other embodiment described herein, wherein the body comprises a plurality of frame sections connected to one another to define an open space.

Example 54. The frame assembly or spring mounted frame assembly, system, device, and method of any of Examples 1-60 or any other embodiment described herein, wherein the plurality of prongs is a first set of prongs and further comprising a second set of prongs, and wherein the second set of prongs extend from one of the frame sections that are not attached to the first set of prongs.

Example 55. A spring mounted frame assembly comprising a body having a loop having a slot defining two free ends defining a non-continuous loop, wherein the body has a non-circular cross-section, and wherein a spring length comprising two free ends and a plurality of interconnected coils is located on the body.

Example 56. The frame assembly or spring mounted frame assembly, system, device, and method of any of Examples 1-60 or any other embodiment described herein, wherein the spring length is a canted coil spring.

Example 57. The frame assembly or spring mounted frame assembly, system, device, and method of any of Examples 1-60 or any other embodiment described herein, wherein the body is formed from a metallic material or a non-metallic material.

Example 58. The frame assembly or spring mounted frame assembly, system, device, and method of any of Examples 1-60 or any other embodiment described herein, further comprising a second spring length comprising two free ends and a plurality of interconnected coils located on the body.

Example 59. The frame assembly or spring mounted frame assembly, system, device, and method of any of Examples 1-60 or any other embodiment described herein, wherein the body contacts an inside surface of each of the interconnected coil.

Example 60. The frame assembly or spring mounted frame assembly, system, device, and method of any of Examples 1-60 or any other embodiment described herein, wherein the body is rotated and has a truncated frusto-conical shape.

Methods of making and of using the frame assemblies and components thereof are within the scope of the present invention.

Although limited embodiments of frame assemblies and their components have been specifically described and illustrated herein, many modifications and variations will be apparent to those skilled in the art. Accordingly, it is to be understood that the frame assemblies and their components constructed according to principles of the disclosed device, system, and method may be embodied other than as specifically described herein. The disclosure is also defined in the following claims.

1-17. (canceled)

18. A frame assembly comprising:
a body comprising a perimeter formed by a plurality of frame sections, including a first frame section and a second frame section, the perimeter defining an open space and each of the first and second frame sections comprising an inner edge;
a first prong extending from the inner edge of the first frame section and extending towards the second frame section, the first prong having an attached end that is attached to the first frame section and a free end that is movable and located adjacent the second frame section;
a second prong spaced from the first prong, the second prong extending from the inner edge of the first frame section or the second frame section and extending towards the other one of the second frame section or the first frame section, the second prong having an attached end that is attached to the first frame section or the second frame section and has a free end that is movable;
a first canted coil spring length comprising a plurality of interconnected coils located on the first prong and a second canted coil spring length comprising a plurality of interconnected coils located on the second prong; and
wherein the body is made from a metal material or a non-metallic material.

19. The frame assembly of claim 18, wherein the second prong extends from the inner edge of the second frame, and further comprising a third prong.

20. The frame assembly of claim 19, wherein the non-metallic material is ceramic or thermoplastic.

21. The frame assembly of claim 18, wherein the first prong has a cross-sectional shape that is oblong or elliptical.

22. The frame assembly of claim 20, wherein the first prong has a cross-sectional shape that is oblong or elliptical.

23. The frame assembly of claim 18, wherein the second prong has a cross-sectional shape that is rectangular or a polynomial shape.

24. The frame assembly of claim 18, wherein the free end of the first prong is movable to separate a gap between the free end and the second frame section from a first gap to a second gap, which is larger than the first gap.

25. The frame assembly of claim 20, wherein the free end of the first prong is movable to separate a gap between the free end and the second frame section from a first gap to a second gap, which is larger than the first gap.

26. The frame assembly of claim 18, wherein each of the first canted coil spring length and the second canted coil spring length has a major axis and a minor axis.

27. The frame assembly of claim 18, wherein the first prong is unitarily formed with the perimeter or is attached to the perimeter.

28. The frame assembly of claim 18, wherein the frame assembly is located between two PC boards to provide at least one of heat transfer, RF shielding, and EMI shielding.

29. The frame assembly claim 18, further comprising a plurality of spaced apart foot support tabs mounted to the perimeter.

30. The frame assembly of claim 18, wherein the first prong and the second prong are part of a plurality of spaced apart prongs, and wherein each of the plurality of prongs has a fixed end that is attached to the first frame section or the second frame section.

31. The frame assembly of claim 30, wherein the frame assembly is located between two PC boards to provide at least one of heat transfer, RF shielding, and EMI shielding.

32. A method of using a spring length without a spring groove comprising:
placing a canted coil spring length comprising a plurality of interconnected coils onto a first prong of a frame assembly having a perimeter formed by a plurality of frame sections, including a first frame section and a second frame section, the perimeter defining an open space and each of the first and second frame sections comprising an inner edge and wherein the first prong is attached to one of the inner edges and extends towards the other inner edge and is spaced from a second prong; and
deflecting the plurality of interconnected coils between two planar surfaces.

33. The method of claim 32, wherein the perimeter defines a plane and wherein the first prong has two rounded ends defining a line along an end cross-section, and wherein the line is angled to the plane.

34. The method of claim 32, wherein each coil has a major axis and wherein the major axis of each coil is angled to the plane.

35. The method of claim 34, wherein the first prong contacts an inside surface of each of the plurality of interconnected coils to turn the major axis.

36. The method of claim 32, wherein deflecting the plurality of interconnected coils between two planar surfaces comprise deflecting the interconnected coils between a first board and a second board.

37. The method of claim 32, wherein the spring length provides at least one of heat transfer, RF shielding, and EMI shielding.
